(19) United States
(12) Patent Application Publication
(10) Pub. No.: US 2010/0161517 A1
(43) Pub. Date: Jun. 24, 2010

(54) SYSTEMS AND METHODS FOR ELECTRICITY METERING FOR VEHICULAR APPLICATIONS

(76) Inventor: Nathan Bowman Littrell, Gardnerville, NV (US)

Correspondence Address: JOHN S. BEULICK (17851);ARMSTRONG TEASDALE LLP, ONE METROPOLITAN SQUARE, SUITE 2600, ST. LOUIS, MO, 63102-2740, US

(21) Appl. No.: 12/341,414

(22) Filed: Dec. 22, 2008

(51) Int. Cl. G01R 11/56

(52) U.S. Cl. 705/412

(57) ABSTRACT

An electricity power meter for use in an electric vehicle is coupled to at least an energy storage device and to a conduit configured to receive electrical charging power from external to the vehicle. Further, the meter is configured to transmit a request for authorization for an electric charging transaction to a vehicle charging station, and receive a response to the request from the vehicle charging station, wherein the response indicates one of an approval and a denial of the request.

### BACKGROUND OF THE INVENTION

The subject matter disclosed herein relates generally to charging of a mobile electric load and more specifically, to metering electricity transferred to an electric vehicle and recognizing the billing and revenue charges based on an amount of electric power transferred to the electric vehicle.

As electric vehicles and hybrid electric vehicles gain popularity, an associated need to accurately manage delivery of electrical energy to such vehicles has increased. Moreover, a need to recognize revenue due to the energy supplier has been created by the increased use of such vehicles. At least some known electric delivery systems provide electric metering at a customer's premises. For example, some known systems use an encoded magnetic strip that is applied to a card to transfer purchase information between a utility billing office and a utility metering and control device located at the customer's premises. A credit meter stored within the control device deducts a value associated with an amount of electricity consumed at the customer's premises. Some of such systems also enable the use of an emergency card that includes a similar encoded magnetic strip when the customer's account with the pre-purchased amount is exhausted. However, generally such systems do not provide for metering of electrical power transferred to a specific electric load using onboard systems, and are thus not compatible for use with electric vehicles.

Moreover, at least some known electricity delivery systems enable mobile metering of electricity use. For example, some of such systems measure power delivered, while work is performed on a power network, using a mobile meter system (MMS) that receives high voltage inputs via secondary side conductors and neutrals of a substation transformer connected to designated terminals on the MMS. The MMS then transforms the inputs using metering instruments and provides currents and voltages that can be metered and are accessible via an external metering cabinet. However, such mobile systems do not measure electricity delivery to electric vehicles using onboard systems.

Furthermore, at least some known systems provide remote monitoring of electricity consumption. For example, some of such systems provide remote monitoring via wireless communication between a communication device associated with an electricity meter and a site controller. More specifically, a communication device receives data from an associated electric meter that is related to an amount of electricity metered, and generates a transmitted message to the site controller using a wireless communication network. However, such systems are intended for use in metering electricity for a site and not for a specific mobile electric load, such as measuring electricity delivery to electric vehicles using onboard systems.

Accordingly, it is desirable to provide systems and methods for metering the amount of electrical power transferred to a mobile electric load, such as an electric vehicle, using onboard systems, and billing a user of such electric vehicle or an account tied to the user or electric vehicle according to the amount of electrical power transferred to the electric vehicle.

### BRIEF DESCRIPTION OF THE INVENTION

In one aspect, an electricity power meter for use in an electric vehicle is coupled to at least an energy storage device and to a conduit configured to receive electrical charging power from external to the vehicle. Further, the meter is configured to transmit a request for authorization for an electric charging transaction to a vehicle charging station, and receive a response to the request from the vehicle charging station, wherein the response indicates one of an approval and a denial of the request.

In another aspect, a system for metering electrical charging power used to charge an energy storage device for use in an electric vehicle includes a conduit configured to receive electrical charging power from external to the electric vehicle and an electricity power meter coupled to at least the energy storage device and to the conduit. The electricity power meter is configured to transmit a request for authorization for an electric charging transaction to a vehicle charging station, and receive a response to the request from the vehicle charging station, wherein the response indicates at least one of an approval and a denial of the request.

In yet another aspect, a method for metering electrical charging power, wherein the charging power is received from a vehicle charging station and is used to charge an energy storage device includes transmitting a request for authorization for an electric charging transaction to a vehicle charging station, and receiving a response to the request from the vehicle charging station, wherein the response indicates either an approval or a denial of the request.

### BRIEF DESCRIPTION OF THE DRAWINGS

FIG. 1 a block diagram of an exemplary electricity power metering system for use with an electric vehicle.

FIG. 2 is a block diagram of an exemplary system for use in metering electrical charging power used to charge an energy storage device coupled to an electric vehicle.

FIG. 3 is a flow chart of an exemplary method for use in metering electrical charging power received from a vehicle charging station and used to charge an energy storage device coupled to an electric vehicle.

FIG. 4 illustrates a user interacting with an exemplary electrical charging power metering system, and with a utility company business system to charge an electric vehicle.

### DETAILED DESCRIPTION OF THE INVENTION

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

In some embodiments, the term “electric vehicle” includes any vehicle that includes one or more electric motors that are used for propulsion, such as an all-electric vehicle that uses only electricity, and a plug-in hybrid-electric vehicle that uses an engine combined with batteries charged by an external power source or an engine and generator, to propel the vehicle. In addition, “electric vehicle” includes any suitable vehicle known to those skilled in the art and guided by the teachings herein, provided that it is capable of performing the functions as described herein.

Moreover, as used herein, the term “meter” broadly refers to: a processor; a computer; a microcontroller; a microcomputer; a programmable logic controller; an application specific integrated circuit; a device used to measure electrical quantities such as Watts, VARs, Volts, and Amperes capable of recording quantities either instantaneously or over a period of time; and any other programmable circuit as known to those skilled in the art and guided by the teachings herein, provided that it is capable of being used as described herein

Technical effects of the methods, systems, and meter described herein include at least one of: transmitting a request for authorization for an electric charging transaction to a vehicle charging station; receiving a response to the request from the vehicle charging station indicating either an approval or a denial of the request; measuring a quantity of electrical charging power received from the vehicle charging station and delivered through meter to energy storage device; transmitting the measurement to the vehicle charging station for a billing determination; and operatively coupling meter to at least one visual display and outputting the measurement in human understandable form to the at least one visual display.

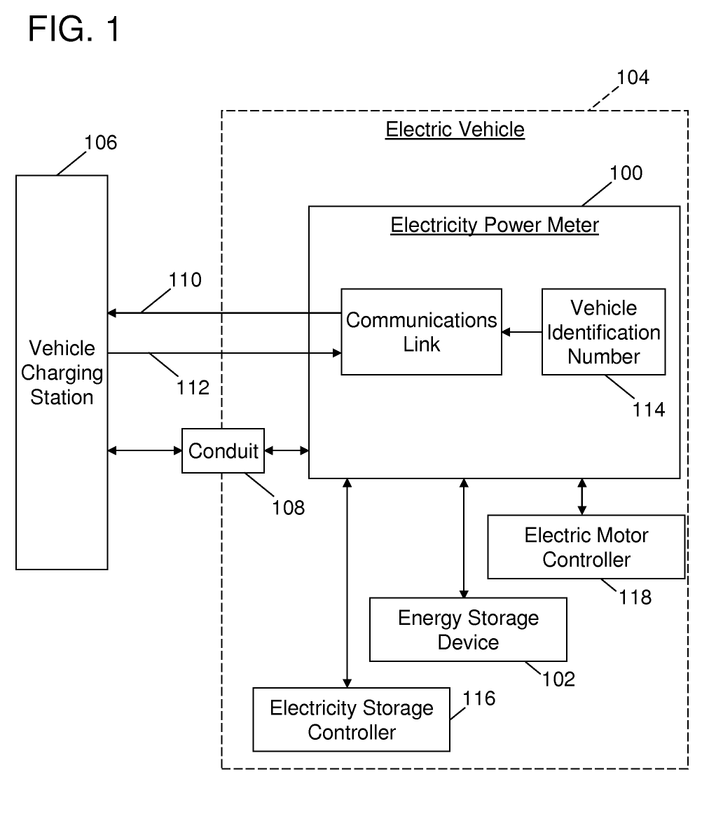

FIG. 1 is a block diagram of an exemplary electricity power metering system 100 for use with an electric vehicle 104. In the exemplary embodiment, an electricity power meter 100 is coupled to at least an energy storage device 102 and to a conduit 108 that may receive electrical charging power from a source outside electric vehicle 104, such as vehicle charging station 106. In the exemplary embodiment, vehicle charging station 106 is capable of providing electrical charging power to one or more electric vehicles 104. Aspects of the invention enable electricity power meter 100 to transmit a request 110 for authorization for an electric charging transaction to vehicle charging station 106, and receive a response 112 indicating either an approval of or a denial of request 110. In some embodiments, request 110 includes a unique vehicle identification number 114 that is embedded within electric vehicle 104 and is accessible by electricity power meter 100.

In other embodiments, after receiving an approval in response 112 to request 110, electricity power meter 100 measures a quantity of electrical charging power received from vehicle charging station 106, as the electrical charging power is delivered through electricity power meter 100 to energy storage device 102. Electricity power meter 100 transmits the measurement to vehicle charging station 106 for a billing determination. In an exemplary embodiment, electricity power meter 100 is coupled to at least one visual display that is on either electric vehicle 104 and/or vehicle charging station 106, to which electricity power meter 100 outputs the measurement of electrical charging power for viewing, in human readable form, by a user.

In another embodiment, electricity power meter 100 is coupled to either an electricity storage controller 116 and/or to an electric motor controller 118 for receiving a value representing a quantity of electrical charging power necessary to fully charge energy storage device 102. Electricity power meter 100 then transmits via request 110, a request for a specific quantity of electrical charging power. By requesting a specific quantity of charging power, a user could be alerted as to an exact cost associated with charging electric vehicle 104 prior to the commencement of the electric charging process. Moreover, such a request enables vehicle charging station 106 to require pre-payment of the cost prior to commencement of the electric charging process. Further, in an alternative embodiment, electricity power meter 100 stores historical data of energy use of electric vehicle 104 on a data storage device (not shown in FIG. 1).

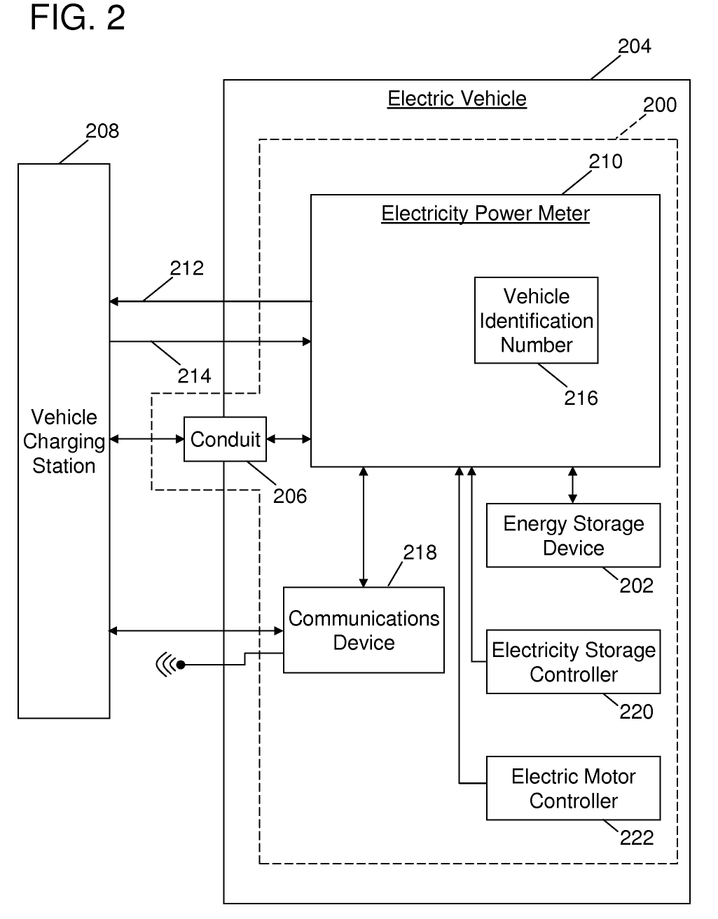

FIG. 2 is a block diagram of an exemplary system 200 for use in metering electrical charging power used to charge an energy storage device 202 coupled to an electric vehicle 204. System 200 includes a conduit 206 that receives electrical charging power from a source external to electric vehicle 204, such as a vehicle charging station 208. In the exemplary embodiment, vehicle charging station 208 is electrically and/or communicatively coupled to one or more electric vehicles 204. An electricity power meter 210 is coupled to either energy storage device 202 and/or conduit 206 for transmitting a request 212 for authorization for an electric charging transaction to vehicle charging station 208, and for receiving a response 214 to the request 212. Response 212 indicates either an approval or a denial of ASDF request 212. In some embodiments, request 212 includes a unique vehicle identification number 216 that is embedded within electric vehicle 204 and that is accessible by electricity power meter 210. In the exemplary embodiment, system 200 also includes a communications device 218 that facilitates communicatively coupling electricity power meter 210 to other compatible devices.

In the exemplary embodiment, after receiving an approval in response 214 to request 212, electricity power meter 210 measures a quantity of electrical charging power received from vehicle charging station 208 and delivered through electricity power meter 210 to energy storage device 202. Further, electricity power meter 210 transmits the measurement to vehicle charging station 208 for a billing determination. In an exemplary embodiment, electricity power meter 210 is coupled to at least one visual display on either vehicle charging station 208 and/or electric vehicle 204, and electricity power meter 210 outputs the measured electrical charging power in human readable form to at least one visual display. In an alternative embodiment, the measurements are stored on a data storage device (not shown in FIG. 2).

In another embodiment, electricity power meter 210 is communicatively coupled to either an electricity storage controller 220 and/or electric motor controller 222 for receiving a value representing a quantity of electrical charging power necessary to fully charge energy storage device 202. Further, in yet another embodiment, request 212 also includes a request for that quantity. This request enables vehicle charging station 208 to alert electricity power meter 210 in electric vehicle 204 as to an exact cost of the charging process. As a result, vehicle charging station 208 may require prepayment for the requested quantity of electrical charging power prior to the commencement of the electric charging process.

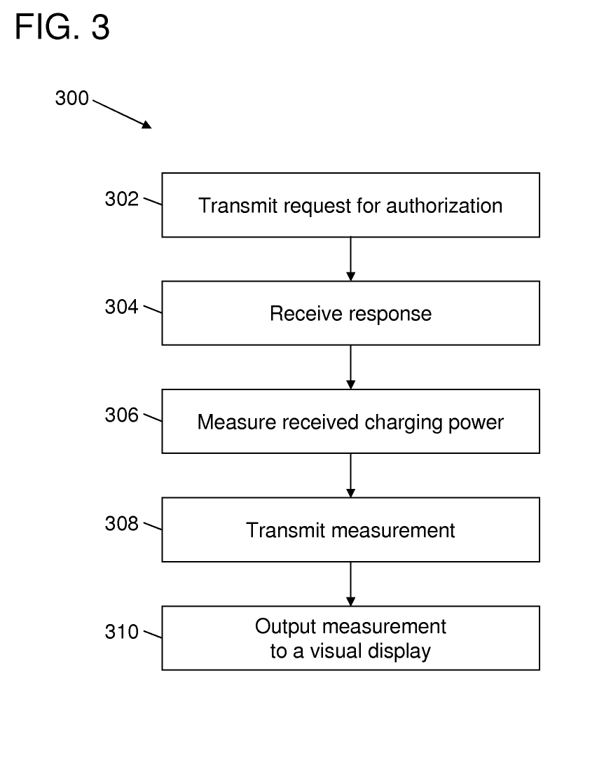

FIG. 3 is a flow chart of an exemplary method 300 for use in metering electrical charging power received from a vehicle charging station and used to charge an energy storage device coupled to an electric vehicle, such as shown in FIG. 2. The method includes transmitting 302 a request for authorization for an electric charging transaction to the vehicle charging station, and receiving 304 a response to the request, from the vehicle charging station, indicating either an approval or a denial of the request. Further, the method includes measuring 306 a quantity of electrical charging power received from the vehicle charging station and delivered through electricity power meter to energy storage device. The measurement is subsequently transmitted 308 to vehicle charging station for a billing determination, and output 310, in human readable form, to at least one visual display.

In an exemplary embodiment, transmitting 302 also includes transmitting a unique vehicle identifier to the vehicle charging station. In the exemplary embodiment, the unique vehicle identifier is used by the vehicle charging station to authorize the request transmitted 302 by the vehicle charging station. In an alternative embodiment, the unique vehicle identifier is predetermined by a manufacturer of electric vehicle. In other alternative embodiments, unique vehicle identifier represents one or more of an electrical charging power supplier account number, a pre-paid stored value account number, a credit account number, a standard vehicle identification number (VIN), and/or any suitable identifying number of a type known to those skilled in the art and guided by the teachings herein, provided that it is capable of being used as described herein. In another embodiment, unique vehicle identifier is only transmitted 302 upon authorization by the user of the electric vehicle such that unauthorized access to the unique vehicle identifier is restricted. In yet another embodiment, a new unique vehicle identifier is generated for each request for authorization for an electric charging transaction.

In various alternative embodiments, one or more of transmitting 302, receiving 304, transmitting 308, and outputting 310, are communicated via either a wireless communication method and/or a wired communication method, such as, for example, via wireless fidelity, broadband over power lines, RFID, and/or any suitable communications method known to those skilled in the art and guided by the teachings herein, provided that it is capable of being used as described herein. Further, in other embodiments, outputting 310 to at least one visual display includes utilizing one or more of a display located on the vehicle charging station, a display located inside the electric vehicle, and a display viewable by an operator of the vehicle charging station.

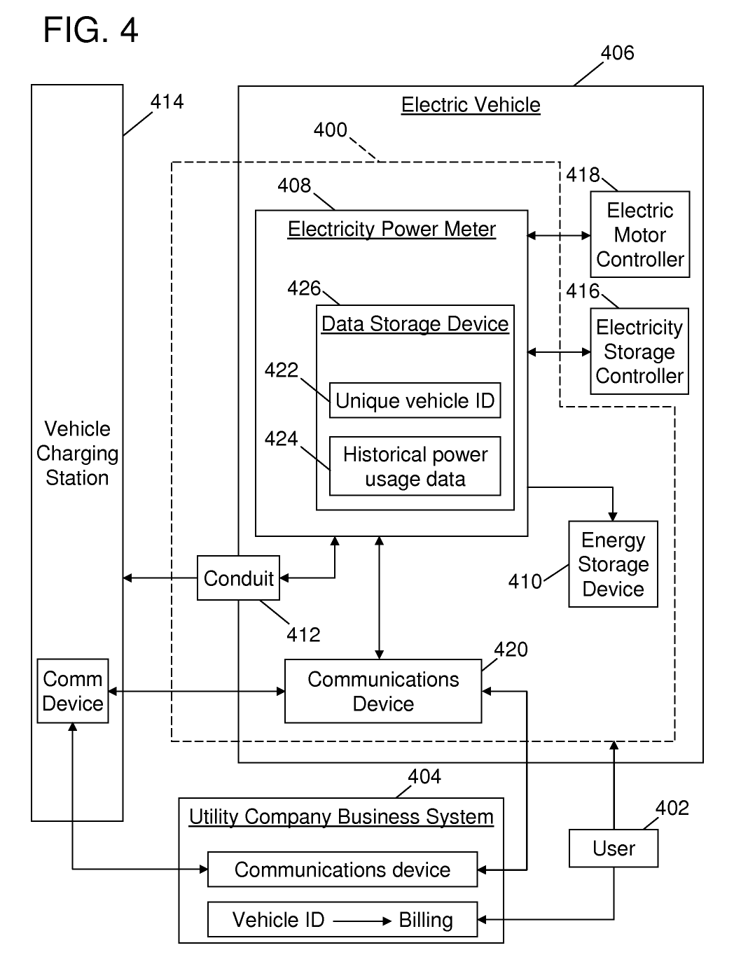

FIG. 4 illustrates a user 402 interacting with an exemplary system 400 for metering electrical charging power, and with a utility company business system 404 to charge an electric vehicle 406. In the exemplary embodiment, system 400 includes an electricity power meter 408 for use in measuring a quantity of electrical charging power delivered from and into an energy storage device 410 coupled to electricity power meter 408, and a conduit 412 for receiving electrical charging power from a source external to electric vehicle 406. Electricity power meter 408 transmits a request for authorization for the electric charging transaction to a vehicle charging station 414, and receives a response from vehicle charging station 414, wherein the response indicates either an approval or a denial of the request. Further, in the exemplary embodiment, system 400 is operatively coupled to at least an electricity storage controller 416, for use, for example, in managing the charging and discharging of energy storage device 410. In addition, in the exemplary embodiment, system 400 is coupled to an electric motor controller 418, for use in managing power output to electric motors (not shown) in electric vehicle 406, and managing power generated by the electric motors during, for example, a regenerative braking process.

In an exemplary embodiment, system 400 includes a communications device 420 that communicatively couples at least a part of system 400 to other compatible devices, such as utility company business system 404. A unique vehicle identifier 422 is transmitted with the request for authorization to vehicle charging station 414. In the exemplary embodiment, utility company billing system 404 uses unique vehicle identifier 422 to authorize the electric charging transaction and to facilitate billing of user 402 for the electric charging transaction. Further, in another embodiment, electricity power meter 408 measures a quantity of electrical charging power received from vehicle charging station 414 and delivered through electricity power meter 408 to energy storage device 410, and transmits the measurement to vehicle charging station 414 for a billing determination.

In an alternative embodiment, electricity power meter 408 stores historical power usage data 424, from power use of electric vehicle 406, on data storage device 426. In yet another embodiment, electricity power meter 408 receives a value representing a quantity of electrical charging power necessary to fully charge energy storage device 410, and includes, in the request for authorization, a request for that quantity. In other embodiments, electricity power meter 408 is coupled to at least one visual display attached to either electric vehicle 406 and/or to vehicle charging station 414, and electricity power meter 408 outputs the measured electrical charging power information, in human readable form, to the at least one visual display,

Exemplary embodiments of an electricity power meter for vehicular applications are described above in detail. The invention is not limited to the specific embodiments described herein, for example, the meter may also be used in a hybrid-vehicle that uses a combination of electricity and engine provided power for movement, and thus is not limited to practice with only the methods and systems as described herein. Rather, the exemplary embodiment can be implemented and utilized in connection with many other electricity storage applications.

In the foregoing specification, it will be evident that various modifications and changes can be made thereto without departing from the broader spirit and scope of the invention. The specification and drawings are, accordingly, to be regarded in an illustrative rather than a restrictive sense.

What is claimed is:

1. An electricity power meter for use in an electric vehicle, said meter coupled to at least an energy storage device and to a conduit configured to receive electrical charging power from external to the vehicle, said meter configured to:
transmit a request for authorization for an electric charging transaction to a vehicle charging station; and
receive a response to the request from the vehicle charging station, wherein the response indicates one of an approval and a denial of the request.

2. An electricity power meter in accordance with claim 1, wherein said meter is further configured to communicatively couple said meter to the vehicle charging station, and wherein said request for authorization includes a unique vehicle identifier.

3. An electricity power meter in accordance with claim 1, wherein said meter is further configured to, upon receiving approval of the request:
measure a quantity of electrical charging power received from the vehicle charging station and delivered through said meter to the energy storage device; and
transmit the measurement of the quantity of received electrical charging power to the vehicle charging station for a billing determination.

4. An electricity power meter in accordance with claim 1, wherein said meter is coupled to at least one visual display, said at least one visual display is coupled to at least one of the electric vehicle and the vehicle charging station, and wherein said meter is further configured to output the measured electrical charging power information in human understandable form to said at least one visual display.

5. An electricity power meter in accordance with claim 1, wherein said meter is communicatively coupled to at least one of an electricity storage controller and an electric motor controller, said meter is configured to receive a value representing a quantity of electrical charging power necessary to fully charge the energy storage device.

6. An electricity power meter in accordance with claim 5, wherein each request for authorization includes a request for the quantity of electrical charging power necessary to fully charge the energy storage device.

7. An electricity power meter in accordance with claim 5, wherein said meter is further configured to store historical data of energy use of the electric vehicle on a data storage device.

8. A system for metering electrical charging power used to charge an energy storage device for use in an electric vehicle, said system comprising:
a conduit configured to receive electrical charging power from external to the electric vehicle;
an electricity power meter coupled to at least the energy storage device and to said conduit, said meter configured to:
transmit a request for authorization for an electric charging transaction to a vehicle charging station; and
receive a response to the request from the vehicle charging station, wherein the response indicates at least one of an approval and a denial of the request.

9. A system in accordance with claim 8, wherein said system further comprises a communications device configured to communicatively couple at least a part of said system to other compatible devices, said communications device is further configured to communicatively couple said meter to the vehicle charging station, and wherein the request includes a unique vehicle identifier.

10. A system in accordance with claim 8, wherein said meter is further configured to, upon receiving approval of the request:
measure a quantity of electrical charging power received from the vehicle charging station and delivered through said meter to the energy storage device; and
transmit the measurement of the quantity of received electrical charging power to the vehicle charging station for a billing determination.

11. A system in accordance with claim 8, wherein said meter is coupled to at least one visual display, said at least one visual display is coupled to at least one of the electric vehicle and the vehicle charging station, said meter is further configured to output the measured electrical charging power information in human readable form to said at least one visual display.

12. A system in accordance with claim 8, wherein said meter is communicatively coupled to at least one of an electricity storage controller and an electric motor controller, said meter configured to receive a value representing a quantity of electrical charging power necessary to fully charge the energy storage device.

13. A system in accordance with claim 12, wherein the request for authorization includes a request for the quantity of electrical charging power necessary to fully charge the energy storage device.

14. A system in accordance with claim 12, wherein said meter is further configured to store historical data of energy use of the electric vehicle on a data storage device.

15. A method for metering electrical charging power, wherein the charging power is received from a vehicle charging station and is used to charge an energy storage device, said method comprising:
transmitting a request for authorization for an electric charging transaction to a vehicle charging station; and
receiving a response to the request from the vehicle charging station, wherein the response indicates either an approval or a denial of the request.

16. A method in accordance with claim 15, further comprising communicatively coupling an electricity power meter to the vehicle charging station, and transmitting a unique vehicle identifier to the vehicle charging station.

17. A method in accordance with claim 15, further comprising:
operatively coupling the electricity power meter to at least the energy storage device and to a conduit, wherein the conduit receives electrical charging power from external to the vehicle; and
upon receiving approval in response to the request,
measuring a quantity of electrical charging power received from the vehicle charging station and delivered through the electricity power meter to the energy storage device, and
transmitting the measurement of the quantity of received electrical charging power to the vehicle charging station for a billing determination.

18. A method in accordance with claim 15, further comprising:
operatively coupling the electricity power meter to at least one visual display, wherein the at least one visual display is coupled to at least one of the electric vehicle and the vehicle charging station; and
outputting the measured electrical charging power information in human understandable form to the at least one visual display.

19. A method in accordance with claim 15, further comprising communicatively coupling the electricity power meter to at least one of an electricity storage controller and an electric motor controller, wherein the electricity power meter receives a value representing a quantity of electrical charging power necessary to fully charge the energy storage device.

20. A method in accordance with claim 19, wherein transmitting the request for authorization further comprises transmitting a request for the quantity of electrical charging power necessary to fully charge the energy storage device.
